(19) United States
(12) Patent Application Publication
(10) Pub. No.: US 2006/0220245 A1
(43) Pub. Date: Oct. 5, 2006

(54) Flip chip package and the fabrication thereof

(76) Inventors: Kwun-Yao Ho, Hsin-Tien City (TW); Moriss Kung, Hsin-Tien City (TW)

Correspondence Address: J C PATENTS, INC., 4 VENTURE, SUITE 250, IRVINE, CA, 92618, US

(21) Appl. No.: 11/099,057

(22) Filed: Apr. 5, 2005

(51) Int. Cl. H01L 23/48; H01L 23/52; H01L 29/40

(52) U.S. Cl. 257/738

(57) ABSTRACT

The invention discloses a flip chip package using an interposer to electrically and mechanically connect the chip and the carrier. The interposer comprises: an insulation layer, two adhesive layers and a plurality of conductive elements. The insulation layer is also the mechanical support of interposer and has one adhesive layer on the first and the second surface for the protection of respective connecting joints on the chip and on the carrier. The conductive elements corresponding to the die pads pass through the insulation layer and adhesive layers, which electrically and mechanically connect to the die pads and respective bump pads. The fabrication thereof comprises: providing the foregoing chip, the foregoing interposer and the foregoing carrier, stacking and aligning the chip, the interposer and the carrier, and bonding the chip, the interposer and the carrier.

### BACKGROUND

This invention relates to a chip package, especially to a flip-chip package and the fabrication thereof.

As the developments of the semiconductor fabrication toward to the nanometer-scale, there are more standard cells formed on the chip having the same area. Then, the chip provides more and more powerful functions to satisfy the different needs. At the same time, the contacts or the die pads on the chip are also developed toward to high count and high density to transmit the various signals.

In respect to the interconnection between the chip and the substrate, the bonding process is necessary to electrically and mechanically connect with the die pads on the chip and the corresponding pads on the substrate. For example, the common bonding technologies are: the wire bonding technique, the tape automatic bonding (TAB) technique, and the flip-chip technique. The flip-chip technique is the most popular one in recent days because it provides a higher contact count and a dense contact arrangement. The wire bonding technique and the TAB technique are only used the around area in the active surface of the chip. However, the flip-chip technique would use the most area in the active surface of the chip to achieve a higher contact count. Besides, the flip-chip package provides a better electrical performance because the signal transmission path between the chip and the substrate is shortened in the flip-chip package.

FIG. 1a˜FIG. 1c schematically illustrate the fabricating steps for a flip-chip package according to the prior art. In FIG. 1a, a plurality of die pads 11 exposed on the active surface 13 of the chip 10. In order to protect against the short-circuit caused by the extra solder and to prevent any damages on the top surface of the substrate, a passivation layer 12 is disposed on the top surface of the substrate. The passivation layer 12 has a plurality of openings to expose a partial surface of the corresponding die pads 11. Then, an under bump metallurgy (UBM) 14 and a bump 15 are sequentially disposed on each exposed surface of the die pad 11. The under bump metallurgy 14 is to enhance the mechanical strength between the bump 15 and the die pad 11.

In order to provide an easier assembly of the chip and the substrate and to enhance the mechanical stress and the reliability of the chip, the chip 10 is disposed on a chip carrier 20 and then is packaged in the molding material. Please referring to FIG. 1b, a plurality of bump pads 21 is formed on a surface 23 of the chip carrier 20. The arrangement of the bump pads 23 is corresponding to the die pads 11. Similarly, a solder mask layer 22 covers the surface 23 to protect the bump pads 21 and the circuits under the surface 23. The solder mask layer 22 has a plurality of openings to expose a partial surface of each bump pads 21 for electrically connections. After aligning and stacking the chip 10 and the chip carrier 20, the bumps 15 on the chip and the bump pads 21 on the chip carrier are bonded together through the soldering process. In other words, the electrical connections of the chip 10 and the chip carrier 20 are achieved. For the easy control in the soldering process, a flux material (not shown in FIG. 1b) may further disposed on the bump pads 21 before aligning and stacking the chip 10 and the chip carrier 20.

Referring to FIG. 1c, the underfill material 30 is filled and injected into the space between the chip 10 and the chip carrier 20. In the underfilling process, the underfill material 30 is injected near the surroundings of the chip and flow into the space by the capillary flow. After the curing of the underfill material 30, a flip-chip package is carried out. The underfill material 30 enhances the bonding strength between the chip 10 and the chip carrier 20. More particularly, it prevents the thermal stress concentrated on the joints between the bumps 15 and the bump pads 21 or on the joints between the bumps 15 and the die pads 11. The stress result from the different thermal expansion will cause the fatigue of the joints and the disconnection of the package. The suitable underfill material 30 further protects the joints of the bumps 15 against the moisture and the chemical reactions. Thus, the underfill material 30 is chose from a polymeric material having the following characteristics: low CTE (coefficient of thermal expansion), low viscosity, insulation, moisture resistance, and chemical resistance. Furthermore, the underfill material 30 does not induce bubbles or voids in the following fabrication process.

The underfilling process is executed after bonding the chip 10 and the chip carrier 20. In order to prevent the voids formed in the space between the chip 10 and the chip carrier 20, the chip charier 20 is heated at 60˜80° C. to enhance the capillarity. Then, the underfill material 30 is baking about 150° C. in the curing process. Thus, the fabrication time and cost are increased in the underfilling process and curing process. In addition, the dimensions of the bumps, the pitches of the bumps, and the arrangements of the bumps will affect the capillarity of the underfill material. In other words, the arrangement of the bumps is limited to prevent the voids generation and to enhance the reliability of the package. Besides, the bumping process to dispose the bumps on the die pads will increase the risk to damage the chips. The fabricating cost is increased because the loss in the bumping process.

In the foregoing descriptions, it is desirable to provide a flip-chip package with a lower cost and a higher reliability and to provide the fabrication thereof.

### SUMMARY

In accordance with the background of the above-mentioned invention, the present invention discloses a flip-chip package to connect with the chip and the chip carrier through an interposer and the fabrication thereof.

In the embodiments according to the present invention, there is an interposer disposed between the chip and the chip carrier. The interposer comprises an insulation layer for mechanical support, a first adhesive layer, a second adhesive layer, and a plurality of conductive elements. The first adhesive layer is disposed on a first surface of the insulation layer; likewise the second adhesive layer is disposed on a second surface of the insulation layer. The conductive elements pass through the insulation layer, the first adhesive layer, and the second adhesive layer. And the dimensions and the arrangement of the conductive elements are corresponding to the die pads of the chip.

The flip-chip package with the interposer comprises a chip, an interposer, and a chip carrier. A plurality of die pads disposes on an active surface of the chip. For the connections between the chip and the chip carrier, the interposer having a plurality of conductive elements corresponding to the die pads, and the chip carrier also having a plurality of bump pads corresponding to the die pads. One die pad electrically connects to the corresponding bump pad through one conductive element. The interposer further comprises an insulation layer for mechanical support and two adhesive layers to bond the chip and to bond the chip carrier, respectively. The fabrication of the flip-chip package through the interposer enhances the mechanical strength and the reliability of the packages.

The fabrication of the flip-chip package comprises providing a chip having a plurality of die pads, providing a chip carrier having a plurality of bump pads, providing an interposer having a plurality of conductive elements, stacking and aligning the chip, the interposer and the chip carrier, and bonding the chip, the interposer and the chip carrier.

Other aspects, features and advantages of the invention will become apparent form the following detailed description, taken in conjunction with the accompanying drawing.

### BRIEF DESCRIPTION OF THE DRAWINGS

Reference will now be made in detail to the present preferred embodiments of the invention, examples of which are illustrated in the accompanying drawings. Wherever possible, the same reference numbers are used in the drawings and the description to refer to the same or like parts.

FIG. 1a shows a cross-sectional view of a chip according to the prior art.

FIG. 1b shows a cross-sectional view of the flip-chip package in the bonding process according to the prior art.

FIG. 1c shows a cross-sectional view of the finished flip-chip package according to the prior art.

FIG. 2a shows a cross-sectional view of the separated elements according to the present invention.

FIG. 2b shows a cross-sectional view of the finished flip-chip package according to the present invention.

FIG. 3 shows a cross-sectional view of the flip-chip package with a sealing material according to the present invention.

FIG. 4 shows a cross-sectional view of the separated elements of the second embodiment according to the present invention.

FIG. 5 shows a cross-sectional view of the first interposer according to the present invention.

FIG. 6 shows a cross-sectional view of the second interposer according to the present invention.

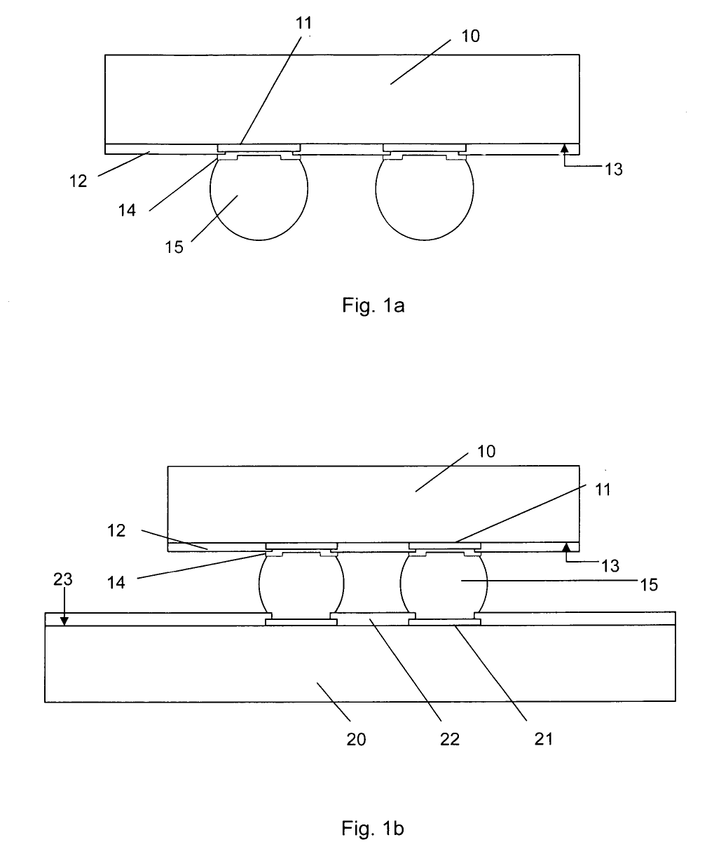

### DESCRIPTION

The present invention provides a flip-chip package having an interposer for the interconnection between the chip and the chip carrier and provides a fabrication thereof.

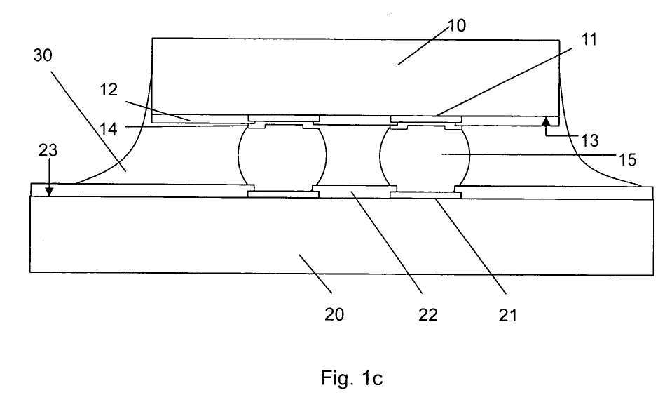

FIG. 2a˜FIG. 2b schematically shows the embodiment and the fabrication steps thereof according to the present invention. In FIG. 2a, a chip 10 has a plurality of die pads 11 disposed on the active surface 13. The top layer of the active surface 13 is a passivation layer 12 to protect the die pads 11 and the circuits under the surface 13. A partial surface of each die pad 11 is exposed because of the corresponding opening of the passivation layer 12. A plurality of bump pads 21 disposed on a surface 23 of the chip carrier 20 corresponds to the die pads 11, one by one. Similarly, a solder mask layer 22 is the top layer of the surface 23 for the protection, and a plurality of openings of the solder mask layer 22 is formed to expose the partial surface of the bump pads 21.

In order to electrically connect with the chip 10 and the chip carrier 20, the embodiment further comprises an interposer 40 disposed between the chip 10 and the chip carrier 20. The interposer 40 comprises an insulation layer 41, a first adhesive layer 42, a second adhesive layer 43, and a plurality of conductive elements 44. The insulation layer 41 is made of a dielectric material for the insulation between the chip 10 and the chip carrier 20 and for the mechanical support of the interposer 40. In addition, the coefficient of thermal expansion (CTE) of the insulation layer 41 is between the CTE of the chip 10 and the CTE of the chip carrier 20. The first adhesive layer 42 is disposed on a first surface of the insulation layer 41, and the second adhesive layer is disposed on a second surface of the insulation layer 41 which is opposite to the first surface. Those adhesive layers are made of polymer, inorganic polymeric composite material, or organic polymeric composite material, such as epoxy resin for example. Those adhesive layers enhance the bonding strength between the chip 10 and the interposer 40 and the bonding strength between the chip carrier 20 and the interposer 40 because these adhesive layers distribute the thermal stress result from the different coefficients of thermal expansion in the chip 10, the chip carrier 20, and the interposer 40. These adhesive layers also provide the protection against moisture and the chemical reaction to reduce the failures in the joints between the chip 10 and the chip carrier 20. The dimensions, the count and the arrangement of the conductive elements 44 depend on those of the die pads 11. One end of each conductive element 44 electrically connects to one die pad 11, and the other end of the conductive element 44 electrically connects to one bump pad 21. In other words, the chip 10 and the chip carrier 20 are electrically connected through the conductive elements 44. For example, the conductive elements 44 is a solder, a metallic material with two solder disposed on two respective ends of the metallic material, or a metallic material with two conductive glues disposed on two respective ends of the metallic material. The solder is the alloy selected from Sn/Pb, Sn/Ag/Cu, Sn/Ag, Sn/Ag/Bi, or Sn/In. The conductive glues have a plurality of conductive particles made of Cu, Au, Ag, Ni or Al. The metallic material is one of Cu, Au, Ag, Ni, and Al, or the conductive glues.

FIG. 2b illustrates to stack and align the chip 10, the interposer 40, and the chip carrier 20, such that each conductive element 44 is in contact with one die pad 11 and one bump pad 21. The width of the interposer 40 is not less than the width of the chip 10 to enhance the bonds between the chip 10 and the interposer 40 and to reduce the cracks occurred at the boundary of the interposer 40. The conductive elements 44 stand out the first adhesive layer 42 and stand out the second adhesive layer 43. Please note that two protruded parts of the conductive elements 44 must match to the height of the passivation layer 12 and match to the height of the solder mask layer 22, respectively. Thus, the first adhesive layer 42 and the chip 10 are laminated without voids; likewise the second adhesive layer 43 and the chip carrier 20 are laminated without voids. In other words, the height of the conductive element 44 is not less than the height of the interposer 40. After heating and pressing on the lamination consist of the chip 10, the interposer 40, and the chip carrier 20, the electrical connection between the chip 10 and the chip carrier 20 is achieved. For example, the conductive element 44 and the die pad 11 are soldered together, and the conductive element 44 and the bump pad 21 are also soldered together in the heating and pressing process. In order to enhance the bonding between the chip 10 and the interposer 40 and the bonding between the chip carrier 20 and the interposer 40, the adhesive layers are polymerized in the curing process by heating the package.

In the foregoing embodiment, the fabrication of the flip-chip package comprises: providing the foregoing chip 10, the foregoing interposer 40, and the foregoing chip carrier 20, stacking and aligning the chip 10, the interposer 40, and the chip carrier 20, and bonding the chip 10, the interposer 40, and the chip carrier 20. The chip 10 has a plurality of die pads 11 as illustrated in foregoing descriptions. In addition, the interposer 40 has a plurality of conductive elements 44, and the chip carrier 20 has a plurality of bump pads 21. Each die pad 11 electrically connects to one bump pad 21 through one conductive element 44 after the bonding process.

The underfilling process is not necessary in the preferred embodiment, thus the cost, the process time, and the failures result from the underfilling process is reduced in the embodiment. Furthermore, the embodiment also keeps away from disposing the bumps on the chip 10. It reduces the risk of damaging the chip 10 in the bumping process and reduces the fabrication cost. In addition, the limitation on the bump arrangement and the limitation on the bump dimension are not necessary because the embodiment is without the underfilling process. In other words, the arrangement of the die pad 11 is more flexible and more efficient to provide the chip with larger count and higher density in contacts.

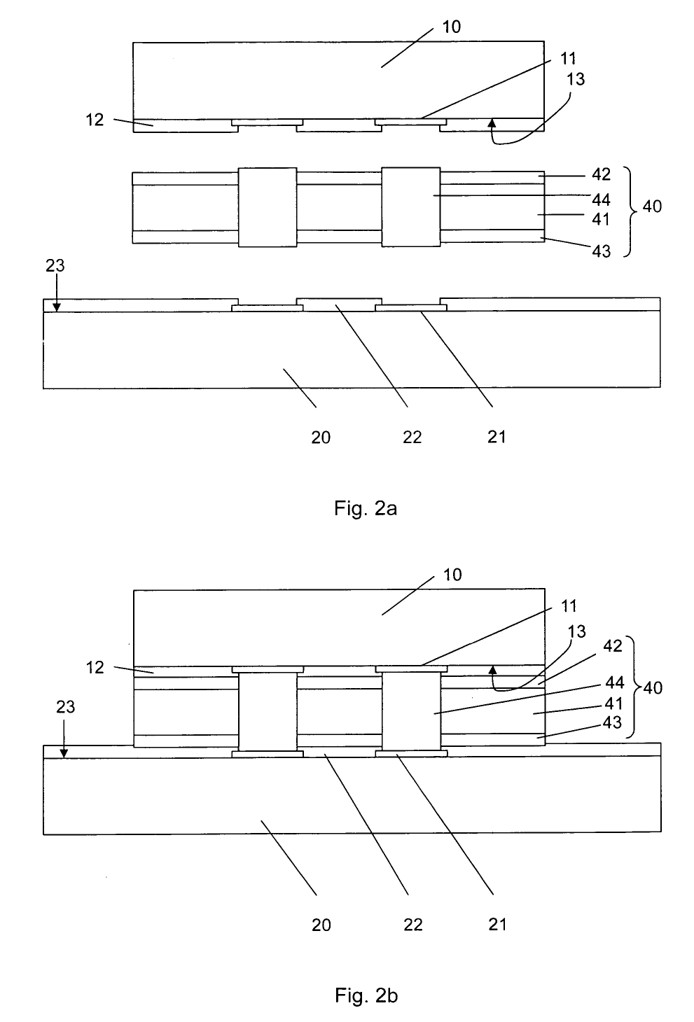

Please referring to FIG. 3, a sealing material 31 covered the interposer 40 and a part of the chip 10 for the reliability of the package and for the enhancing protection of the package. The sealing material 31 which is similar to the underfill material in the prior art has the following characteristics: low viscosity, insulation, moisture resistance, chemical resistance, and bubble-free. Thus, the protection for the joints and the reliability of the package are enhanced.

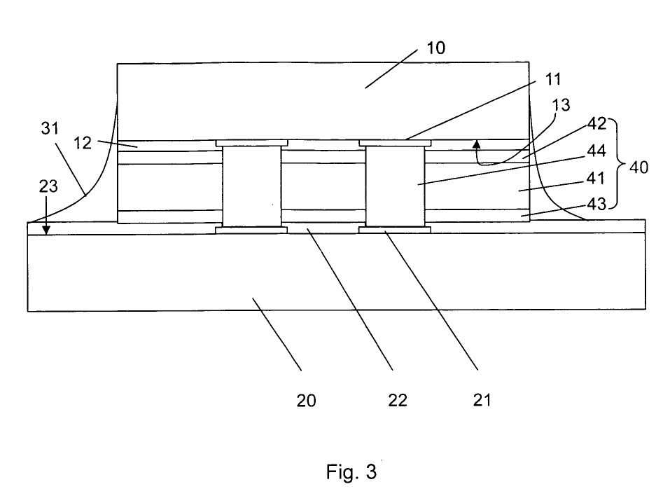

For a stronger mechanical strength in the joints and an easier soldering process, other media could further disposed between the chip 10 and the interposer 40 and between the chip carrier 20 and the interposer 40. Referring to FIG. 4, a under bump metallurgy (UBM) 14 is disposed on the die pad 11. The UBM 14 forms a solderable surface to strengthen the joints and to improve the efficiency of soldering process. On the other hands, a flux 24 could be disposed on the bump pad 21 before stacking the chip carrier 20 and the interposer 40. Similarly, the flux could be disposed on the die pads 11 or on the UBM 14 if necessary.

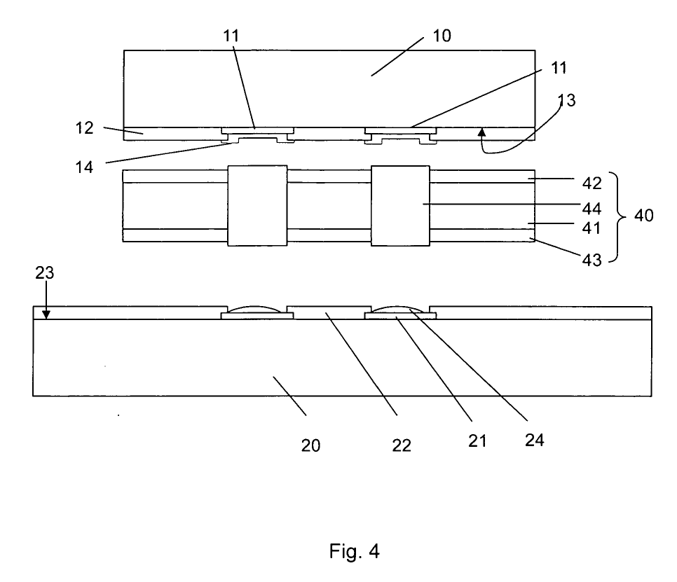

FIG. 5 illustrates an embodiment about the interposer 50 according to the present invention. The interposer 50 is a five-layered lamination which is comprises: an insulation layer 51, a first adhesive layer 52, a second adhesive layer 53, a first removable layer 55, and a second removable layer 56. The insulation layer 51 is made of polymer, ceramics, glass, or composite isolation material, such as polyimide for example. The first adhesive layer 52 is further disposed on the first surface of the insulation layer 51, and the first removable layer 55 is disposed on the first adhesive layer 52 sequentially. Similarly, the second adhesive layer 53 and the second removable layer 56 are sequentially stacked on the second surface of the insulation layer 51. To connect with the die pads 11, the corresponding vias is formed to pass through the interposer 50, by the laser drilling for example. The conductive elements 54 are disposed by filling the solder into the vias. The removable layer 55 and 56, made of PET for example, protect those adhesive layers against the dirt and the impurity. Before stacking the interposer 50, the chip 10, and the chip carrier 20, the removable layer 55 and 56 is removed by mechanical or chemical method to expose those adhesive layers underneath. The solder 54 is protruded with the removable layer 55 and 56 because of the surface tension of the solder material. Although the protruded height from the removable layer is hard to control for different needs, the protruded height from the adhesive layer is controlled by the thickness of the removable layers. More particularly, the protruded height from the first adhesive layer 52 is dependent on the thickness of the first removable layer 55, and the protruded height from the second adhesive layer 53 is dependent on the thickness of the second removable layer 56. For different thicknesses of the passivation layer and the solder mask layer, the optimized interposers 50 with suitable protruded height could be fabricated to match the chip and the chip carrier.

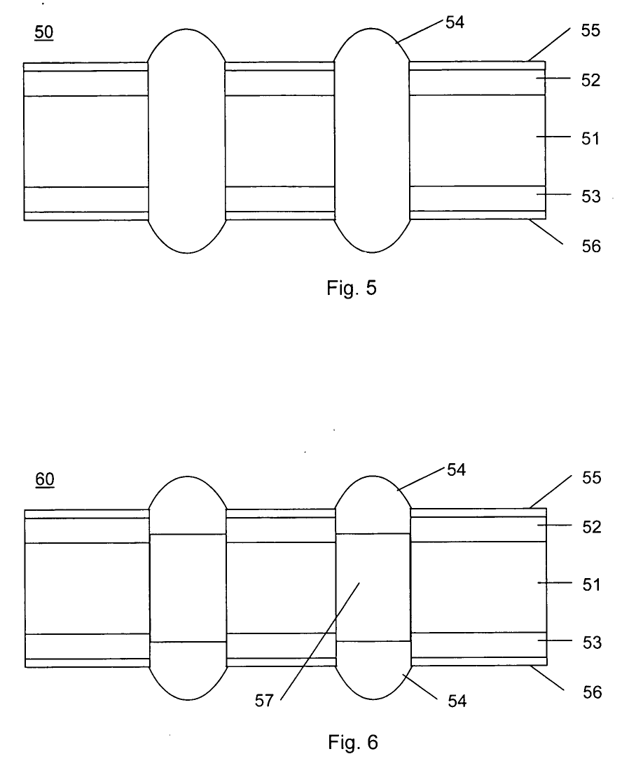

Other embodiments of the invention will appear to those skilled in the art from consideration of the specification and practice of the invention disclosed herein. Please referring to FIG. 6, the conductive element of the interposer 60 comprises a metallic material 57, such as copper, silver, gold, nickel, or aluminum, filled into the via by the electric plating. Then, the solders 54 are respectively formed on two ends of the metallic material 57 by dip soldering solder printing or electroplating. The conductive glues could replace with the solders 54 disposed on the ends of the metallic material 57. Furthermore, the conductive glues comprise the metallic particles made of copper, silver, gold, nickel, or aluminum. In respect to the stacking step and the soldering step, it is not limited to stacking or soldering all of the chip, the interposer and the chip carrier in the same step. It is also possible to stacking and soldering the interposer with one of the chip and the chip carrier. Then, stacking and soldering the interposer with the other one to carry out the package.

According to the above, the present invention has at least the following advantages:

1. Providing a flip-chip package without the bumping process and the fabrication thereof. Time and the risk in chip damage result from the bumping process is reduced, thus the fabricating cost is reduced.

2. Providing a flip-chip package without the underfilling and the fabrication thereof. It further reduces the cost and improves the reliability of the package.

3. Enhancing the reliability of the package because of the well protections on the joints and the tight matches between the chip and the interposer and between the interposer and the chip carrier.

4. Providing a flip-chip package having a higher contact count, a higher contact density and a more flexible contact arrangement.

Although the invention is illustrated and described herein as embodied in one or more specific examples, it is nevertheless not intended to be limited to the details shown, since various modifications and structural changes may be mode therein without departing from the spirit of the invention and within the scope and claims be constructed broadly and in a manner consistent with the scope of the invention, as set forth in the following claims.

What is claimed is:

1. An interposer for the electrical connections between a chip and a chip carrier, comprising:
an insulation layer having a first surface and a second surface;
a first adhesive layer disposed on the first surface of the insulation layer;
a second adhesive layer disposed on the second surface of the insulation layer; and
a plurality of conductive elements disposed in the insulation layer, wherein the conductive elements passing through the insulation layer, the first adhesive layer, and the second adhesive layer to electrically connect with the chip and the chip carrier.

2. The interposer of claim 1, further comprising a first release layer disposed on the first adhesive layer.

3. The interposer of claim 2, further comprising a second release layer disposed on the second adhesive layer.

4. The interposer of claim 1, wherein one of the conductive elements is made of a solder.

5. The interposer of claim 1, wherein one of the conductive elements is made of a metallic material and two solders on two ends of the metallic material or is made of a metallic material and two conductive glues on two ends of the metallic material.

6. The interposer of claim 5, wherein the metallic material is one of copper, silver, gold, nickel, and aluminum, and the conductive glues have a plurality of metallic particles made of one of copper, silver, gold, nickel, and aluminum.

7. A flip-chip package, comprising:
a chip having a plurality of die pads;
a chip carrier having a plurality of bump pads respectively corresponding to the die pads; and
an interposer between the chip and the chip carrier having a plurality of conductive elements respectively corresponding to the die pads, wherein each conductive element has a first end electrically connected to one of the die pads and a second end electrically connected to one of the bump pads.

8. The flip-chip package of claim 7, wherein the interposer further comprises an insulation layer, a first adhesive layer for the bond between the insulation layer and the chip, and a second adhesive layer for the bond between the insulation layer and the chip carrier.

9. The flip-chip package of claim 8, wherein the insulation layer has a first coefficient of thermal expansion between a second coefficient of thermal expansion of the chip and a third coefficient of thermal expansion of the chip carrier.

10. The flip-chip package of claim 7, wherein one of the conductive elements is made of a solder.

11. The flip-chip package of claim 7, wherein one of the conductive elements is made of a metallic material and two solders on two ends of the metallic material or is made of a metallic material and two conductive gules on two ends of the metallic material.

12. The flip-chip package of claim 11, wherein the metallic material is one of copper, sliver, gold, nickel, and aluminum, and the conductive glue comprising a plurality of metallic particles which is made of one of copper, sliver, gold, nickel, and aluminum.

13. The flip-chip package of claim 7, wherein one of the conductive elements has a first thickness which is not less than a second thickness of the interposer.

14. The flip-chip package of claim 7, wherein the interposer has a first width which is not less than a second width of the chip.

15. The flip-chip package of claim 7, further comprising a sealing material around the chip covering the interposer and a part of the chip.

16. A fabricating method of a flip-chip package, comprising:
providing a chip which has a plurality of die pads;
providing a chip carrier which has a plurality of bump pads respectively corresponding to the die pads;
providing an interposer which comprises an insulation layer, a first adhesive layer disposed on a first surface of the insulation layer, a second adhesive layer disposed on a second surface of the insulation layer, and a plurality of conductive elements passing through the insulation layer, the first adhesive layer and the second adhesive layer;
stacking and aligning the chip, the interposer, and the chip carrier, wherein the interposer is disposed between the chip and the chip carrier; and
bonding the chip, the interposer, and the chip carrier, such that one of the die pads on the chip and one of the bump pads on the chip carrier are electrically connected through one of the conductive elements.

17. The fabricating method of claim 16, wherein the step of stacking and aligning the chip, the interposer, and the chip carrier further comprises stacking and aligning the interposer and the chip carrier and stacking and aligning the chip and the interposer.

18. The fabricating method of claim 16, wherein the step of bonding the chip, the interposer, and the chip carrier further comprises bonding the chip and the interposer and bonding the interposer and the chip carrier.

19. The fabricating method of claim 16, further comprising curing the first adhesive layer and the second adhesive layer.

20. The fabricating method of claim 16, wherein the step of bonding the chip, the interposer, and the chip carrier comprises a heating process and a pressing process.
